(19) United States
(12) Patent Application Publication
(10) Pub. No.: US 2008/0084236 A1
(43) Pub. Date: Apr. 10, 2008

(54) SERVO LOOP CIRCUIT FOR CONTINUOUS TIME DC OFFSET CANCELLATION

(75) Inventor: Yuan-hung Chung, Jhudong Township (TW)

Correspondence Address: MADSON & AUSTIN, 15 WEST SOUTH TEMPLE, SUITE 900, SALT LAKE CITY, UT, 84101, US

(73) Assignee: MediaTek Inc., Hsin-Chu City (TW)

(21) Appl. No.: 11/538,783

(22) Filed: Oct. 4, 2006

(51) Int. Cl. H03L 5/00

(52) U.S. Cl. 327/307

(57) ABSTRACT

A servo loop circuit suitable for DC offset cancellation in a direct conversion receiver. The servo loop in accordance with the present invention has a low pass filtering device with a smoothly and continuously changed corner frequency, so that the response time of the low pass filtering device can be limited to a short period of time without inducing in additional DC offset. The smoothly and continuously changing of the corner frequency is performed by providing a continuously variable resistance by at least one continuously variable resistive unit, which may be implemented by transistor technique. The resistance of the continuously variable resistive unit is continuously varied by smoothly controlling the level of a voltage signal applied thereto.

### TECHNICAL FIELD OF THE INVENTION

The present invention relates to a servo loop for removing DC offset in a receiver, more particularly, to a servo loop including a low pass filtering device. A corner frequency of the low pass filtering device is continuously varied to achieve a required low cutoff frequency.

### BACKGROUND OF THE INVENTION

In a direct conversion receiver (DCR), a radio frequency (RF) signal is received and down converted by a mixer to a baseband signal. The mixer down converts the RF signal with a local oscillation signal supplied by a local oscillator (LO) operating at a frequency close to the RF frequency.

FIG. 1 shows a simple example of a DCR. As shown, The received RF signal is amplified by a variable gain amplifier (VGA) 110, then is down converted by a mixer 125 to a baseband signal with a LO signal provided by a local oscillator 120. The baseband signal is then filtered by a low pass filter 130 to filter out high frequency components caused by the mixing of the RF signal and the LO signal, while retaining the baseband signal components. Then the baseband signal is amplified by an amplifier 150.

However, The LO signal tends to leak into the RF input port, causing a phenomenon of self mixing. A large DC offset component is then induced at the mixer output. If the DC offset component is amplified by the amplifier 150, it is likely to cause the successive stage, such as an analog-to-digital converter (ADC), to be saturated. Accordingly, it is an essential topic to deal with the DC offset. A method to remove the DC offset is to provide a servo loop in the receiver.

As shown in FIG. 1, the output of the amplifier 150 is fed back to a low pass filter 160. The low pass filter 160 substantially passes the DC component in the baseband signal. The output of the low pass filter 160 is passed to the DC amplifier to be amplified. Then the amplified DC component is fed to a subtractor 140. The subtractor 140 subtracts the feedback DC signal from the output of the low pass filter 130 to cancel the DC offset existing therein.

The servo loop with the feedback low pass filter expresses an effect of a high pass filter in order to filter out the DC offset component in the baseband signal. As can be easily understood, the corner frequency must be very low. It means that the RC response time is very long, this is undesirable.

A method to solve this problem is switching the corner frequency. The corner frequency is not set at the required low frequency at a time, instead, the corner frequency is set to a high corner frequency at first, and is shifted to a required low corner frequency through several switchings. For example, the corner frequency is set to 1 MHz at the first time, and then is switched from 1 MHz to 300 kHz, from 300 kHz to 100 kHz, from 100 kHz to 10 kHz, and so on. Finally, a low corner frequency is obtained. By this method, the settle time can be limited to an acceptable shorter time period. Such a switching operation can be implemented by a resistor network, which can be controlled to provide several different resistances

However, the discrete switching of the resistances causes additional DC offset to be generated, which will be further explained later.

### SUMMERY OF THE INVENTION

The present invention is to provide a servo loop circuit for DC offset cancellation. The servo loop is used in a direct conversion receiver, for example. The servo loop in accordance with the present invention has a low pass filtering device with a smoothly and continuously changed corner frequency, so that the response time of the low pass filtering device can be limited to a short period of time without inducing in additional DC offset.

According to the present invention, the smoothly and continuously changing of the corner frequency of the low pass filtering device in the servo loop is performed by providing a continuously variable resistance in the low pass filtering device.

In an embodiment of the present invention, the low pass filtering device includes a continuously variable resistive unit. The resistance of the continuously variable resistive unit is continuously varied by smoothly controlling the level of a voltage signal applied thereto. In the embodiment, the continuously variable resistive unit utilizes transistor technique to provide continuously varied resistance.

In another embodiment of the present invention, the servo loop circuit further includes a gain device for providing a gain to an input signal.

### BRIEF DESCRIPTION OF THE DRAWINGS

The present invention will be further described in details in conjunction with the accompanying drawings. In the drawings, the like reference numbers indicate the similar elements.

FIG. 1 schematically illustrates a basic architecture of a prior art direct conversion receiver with a servo loop;

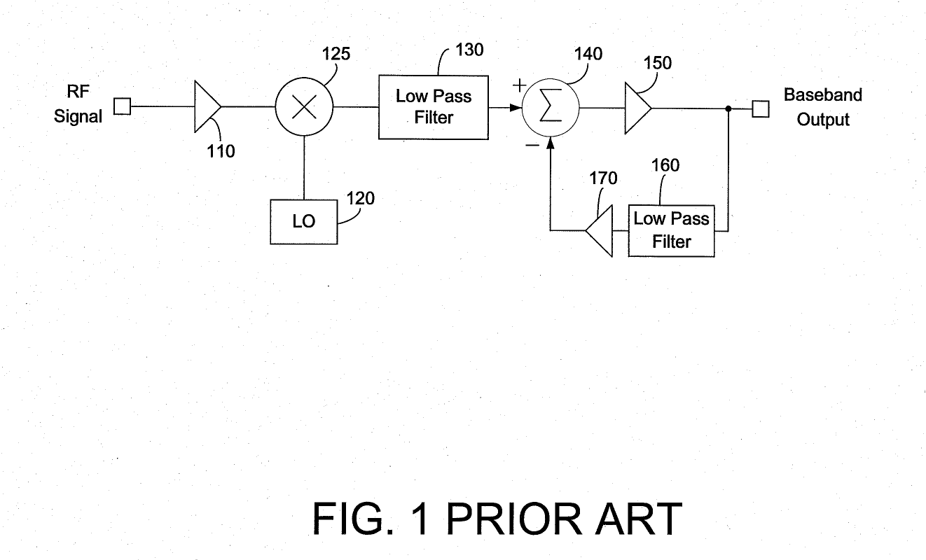

FIG. 2 schematically shows an embodiment of a servo loop circuit in accordance with the present invention;

FIG. 3 schematically shows another embodiment of the servo loop circuit in accordance with the present invention;

FIG. 4 illustrates an exemplary DC offset canceller with the servo loop circuit in accordance with the present invention;

FIG. 5 shows an implementation of a continuously variable resistive unit of the servo loop circuit in accordance with the present invention;

FIG. 6 shows relationship between the equivalent resistance of the continuously variable resistive device of FIG. 5 and control voltage applied thereto; and

FIG. 7 illustrates an example of a low pass filtering device of the servo loop circuit in accordance with the present invention.

### DETAILED DESCRIPTION OF THE INVENTION

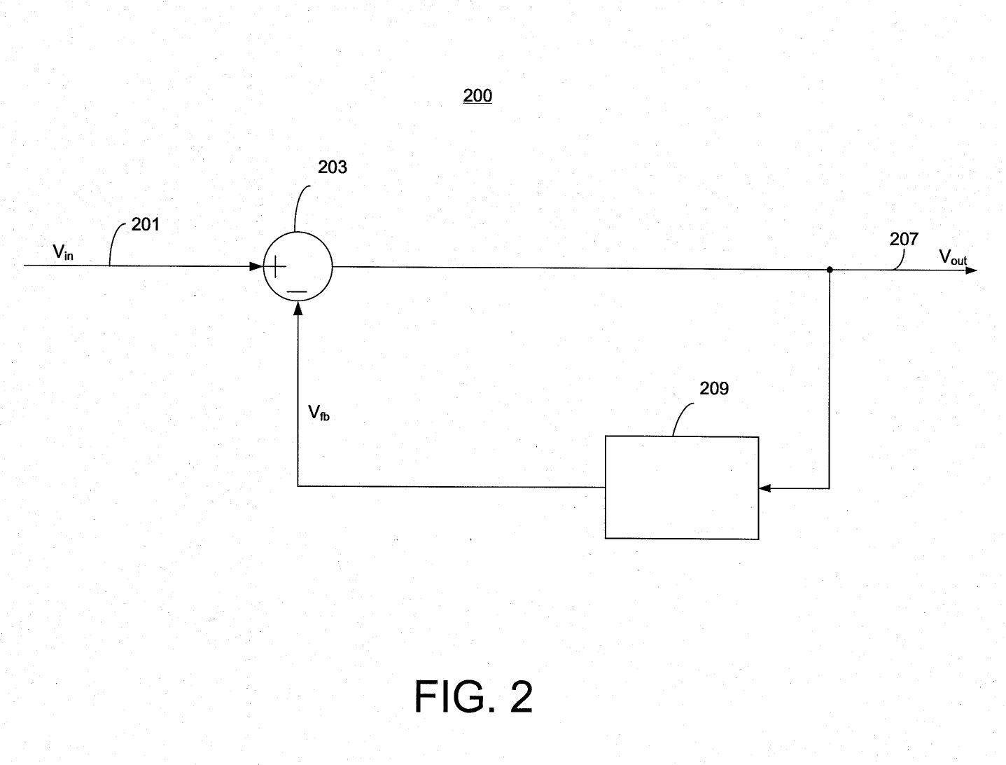

FIG. 2 schematically shows an embodiment of a servo loop circuit 200 in accordance with the present invention. The servo loop 200 is used for removing low frequency signal components, such as DC offset in direct conversion receiver application. The servo loop circuit 200 has a signal path with an input port 201 for an input signal Vᵢₙ to enter, and an output port 207 for an output signal Vₒᵤₜ to transmit to a successive stage. The servo loop circuit 200 further has a low pass filtering device 209. The output signal Vout is fed back to the low pass filtering device 209, so that only the low frequency signal components, such as DC offset, may pass. The feedback low frequency signal components V_{fb} (e.g. feedback DC offset) is subtracted from the signal Vᵢₙ by a subtractor 203 to remove the DC offset therein.

The low pass filtering device 209 can be implemented with any suitable techniques, such as a traditional low pass filter or an integrator.

The corner frequency of the low pass filtering device 209 is decided by capacitance and resistance thereof. According to the invention, the resistance of the low pass filter device 209 is continuously variable. The relevant details will be further described later.

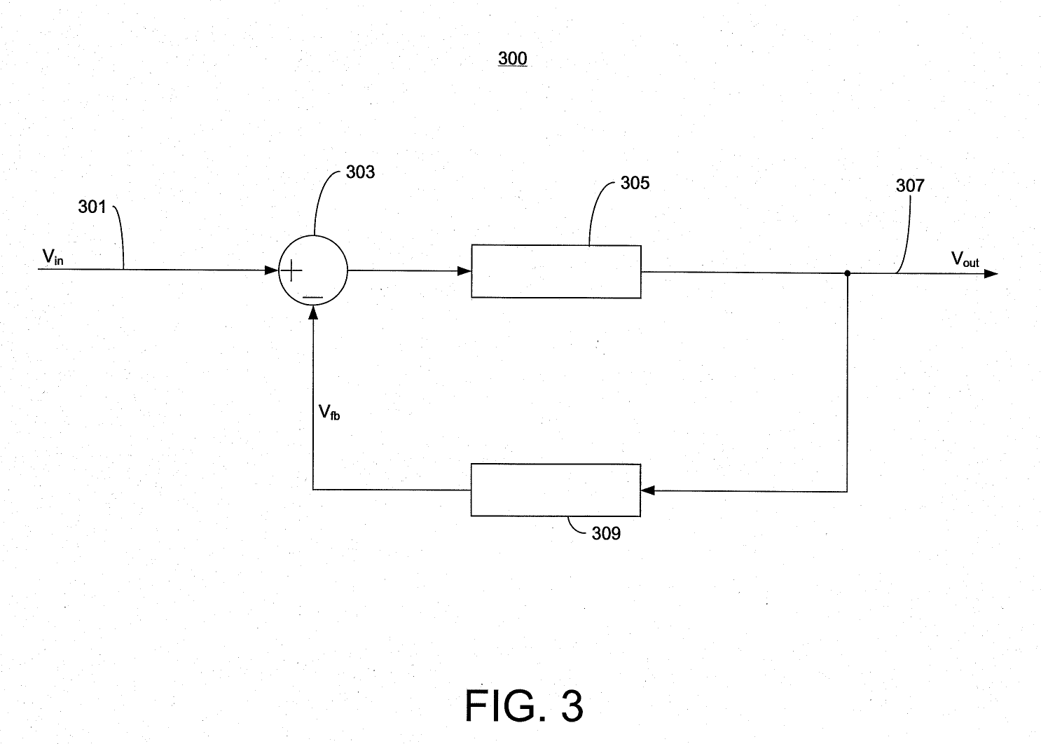

FIG. 3 schematically shows another servo loop circuit 300 in accordance with the present invention. The servo loop circuit 300 has an input port 301 for an input signal Vᵢₙ to enter, and an output port 307 for an output signal Vₒᵤₜ to transmit to a successive stage. The servo loop circuit 300 further has a gain device 305 for providing a gain A. Accordingly, the ideal relationship between the Vᵢₙ and Vₒᵤₜt is:

Vₒᵤₜ=A·Vᵢₙ (1)

As the servo loop circuit 200, the servo loop circuit 300 also has a low pass filtering device 309 with continuous variable resistance. The output signal Vₒᵤₜ is fed back to the low pass filtering device 309, so that only the low frequency signal components, such as DC offset, may pass. The feedback low frequency signal components V_{fb} (e.g. feedback DC offset) is subtracted from the signal Vᵢₙ by a subtractor 303, so that the DC offset existing in the signal can be cancelled.

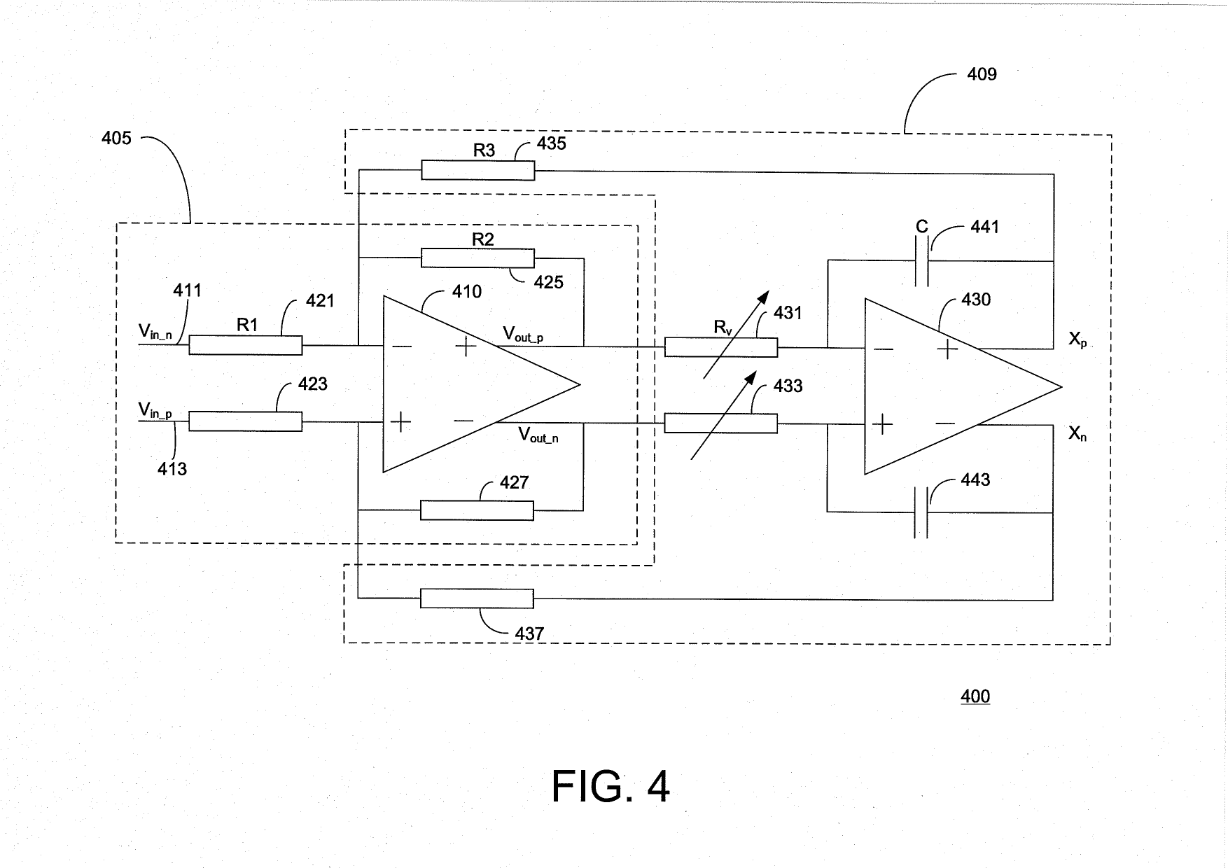

FIG. 4 illustrates an exemplary servo loop circuit 400 with the servo loop circuit in accordance with the present invention. The servo loop circuit 400 may be used with balanced input signals Vᵢₙ_{_{—}}ₙ and Vᵢₙ_{_{—}}ₚ, for example.

The servo loop circuit 400 comprises a gain device 405 having a differential amplifier 410, which is used to amplify an input signal (signal differential components Vᵢₙ_{_{—}}ₙ and Vᵢₙ_{_{—}}ₚ) provided at input terminals 411 and 413. The input signal differential components Vᵢₙ_{_{—}}ₙ and Vᵢₙ_{_{—}}ₚ are fed into the amplifier 410 via resistors 421 and 423, respectively. The resistors 421 and 423 are of a resistance R1. Output signal components Vₒᵤₜ_{_{—}}ₚ and Vₒᵤₜ_{_{—}}ₙ of the amplifier 410 are fed back to the input terminals thereof via resistors 425 and 427, respectively. The resistors 425 and 427 are of a resistance R2. The output signal components Vₒᵤₜ_{_{—}}ₚ and Vₒᵤₜ_{_{—}}ₙ of the amplifier 410 are output to a low pass filtering device 409.

In the low pass filtering device 409, an amplifier 430, resistors 431, 433 and capacitors 441, 443 constitute an integrator. The resistors 431, 433 are implemented by continuously variable resistive units with a variable resistance Rv. The outputs Xₚ, Xₙ of the integrator are fed back to the amplifier 410 of the gain device 405 via resistors 435, 437. The resistors 435, 437 are of a resistance Rf.

The relationship between the input signal Vᵢₙ and output signal Vₒᵤₜ approximately satisfies the following equation:

$$\frac{Δ {V}_{out}}{Δ {V}_{i n}} = \frac{R 2}{R 1} \cdot \frac{Rv \cdot s \cdot C}{\frac{R 2}{Rf} + Rv \cdot s \cdot C} \qquad ( 2 )$$

### Wherein: s=jω

The relationship between the output signal Vₒᵤₜ and the input signal Vᵢₙ also approximately satisfies the equation:

$${V}_{out} ( t ) = \frac{R 2}{R 1} \cdot {V}_{i n} ( t ) + \frac{R 2}{Rf} \cdot X ( t ) \qquad ( 3 )$$

Wherein X(t) is the output of the amplifier 430, which can be expressed as:

$$X ( t ) = \frac{- 1}{RvC} \int {V}_{out} ( t ) d t \qquad ( 4 )$$

### If it is set

$${R}_{eff} = Rv \cdot \frac{Rf}{R 2} \qquad ( 5 )$$

Then equation (3) can be:

$${V}_{out} ( t ) = \frac{R 2}{R 1} \cdot {V}_{i n} ( t ) - \frac{1}{C \cdot {R}_{eff}} \cdot \int {V}_{out} ( t ) d t \qquad ( 6 )$$

### Assume the initial condition of Vₒᵤₜ(t) is V₀, then

$${V}_{out} ( t ) = \frac{{\int }_{0}^{t} f ( {t}^{′} ) \cdot \frac{\frac{R 2}{R 1} \cdot d {V}_{i n} ( {t}^{′} )}{d {t}^{′}} d {t}^{′} + Vo}{f ( t )} \\ f ( t ) = {e}^{{\int }_{0}^{t} \frac{1}{{R}_{eff} \cdot C} d {t}^{′}} \qquad ( 7 )$$

If the cutoff frequency is defined as:

$${ω}_{T} = \frac{1}{{R}_{eff} \cdot C} \qquad ( 8 )$$

The input signal Vᵢₙ(t) is expressed as:

$${V}_{i n} ( t ) = {\sum }_{n = 0}^{m} An \cdot {e}^{j ( {ω}_{n} \cdot t + {φ}_{n} )} \qquad ( 9 )$$

### Wherein An is the amplitude of the signal.

Then, the output signal Vₒᵤₜ(t) is:

$${V}_{out} ( t ) = {\sum }_{n = 1}^{m} \{ \frac{\frac{R 2}{R 1}}{1 - j \cdot \frac{{ω}_{{T}^{′}}}{{ω}_{n}}} \cdot {A}_{n} \cdot {e}^{j ( {ω}_{n} \cdot t + {φ}_{n} )} + \underbrace{\frac{\frac{R 2}{R 1} \cdot {A}_{n} \cdot {e}^{j \cdot {φ}_{n}}}{f ( t )} \cdot [ \frac{\frac{j ( {ω}_{{T}^{′}} - {ω}_{T} )}{{ω}_{n}}}{( 1 - j \cdot \frac{{ω}_{{T}^{′}}}{{ω}_{n}} ) \cdot ( 1 - j \cdot \frac{{ω}_{T}}{{ω}_{n}} )}}_{DC} ] \} \qquad ( 10 )$$

As can be seen from equation (10), the DC offset (indicated by “DC” term) is proportional to R2/R1, An, and the term (ω_{T}−ω_{T}). The term (ω_{T}−ω_{T}) indicates the switching step between the cutoff frequencies. That is, when the corner frequency of the low pass filtering device in the servo loop circuit is discretely switched, there will be a problem of DC offset generation. This problem is significantly serious especially when the switching step is very large, such as 1 MHz to 300 kHz.

Accordingly, smoothly changing the cutoff frequencies is preferred. By using the continuously variable resistors 431 and 433, which have continuously variable resistance Rv, this goal can be achieved.

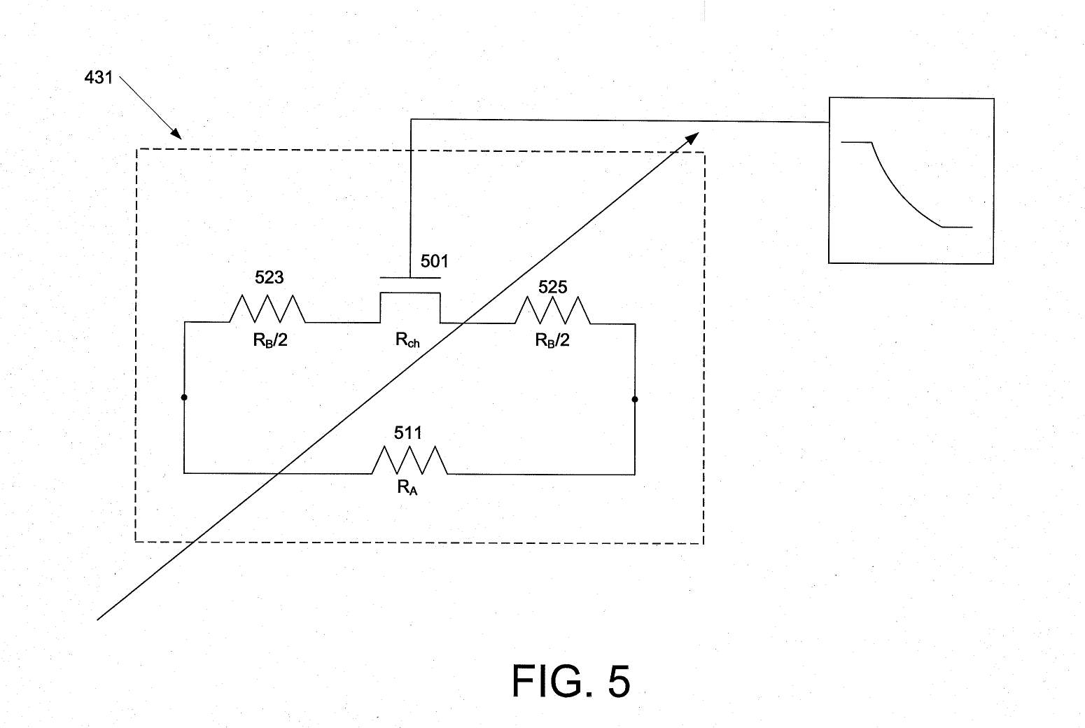

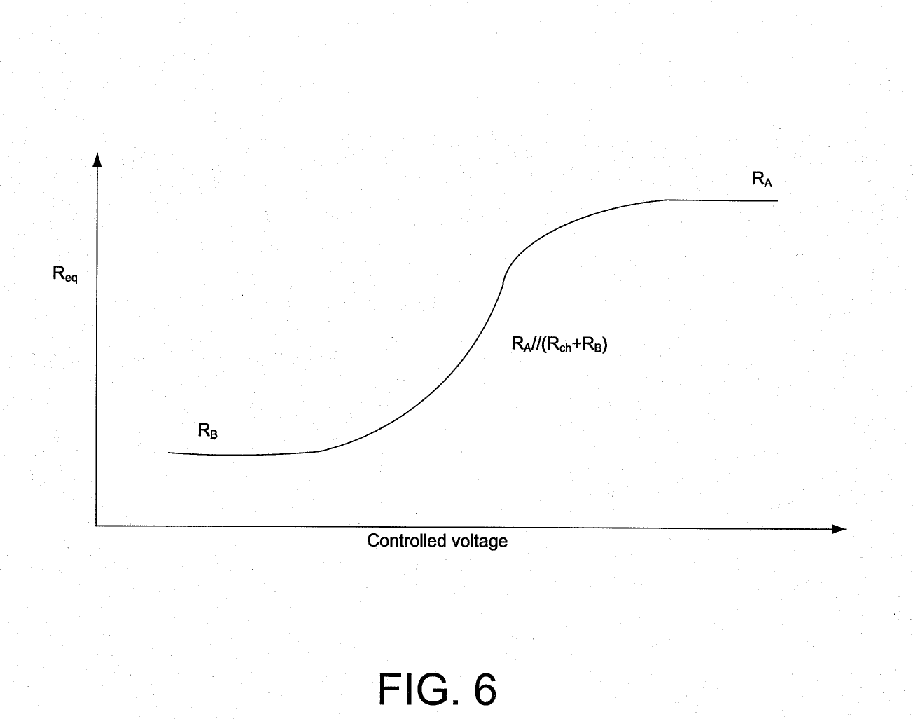

FIG. 5 shows an implementation of the continuously variable resistive unit 431 of low pass filtering device 405 in the servo loop circuit in accordance with the present invention. As shown, the continuously variable resistive unit 431 comprises a transistor 501 with a resistance R_{ch}, resistor 511 of resistance R_{A}, and resistors 523, 525 respectively of resistance R_{B}/2. Therefore, the equivalent resistance R_{eq} of the continuously variable resistive unit 431 is R_{A}//(R_{ch}+R_{B}). The resistance R_{ch} of the transistor 501, which is preferably implemented by a MOS, is varied by controlling a voltage applied to a gate thereof. When a continuously controlled voltage signal is applied to the transistor 501, the equivalent resistance of the continuously variable resistive unit 431 varies continuously. The variation of the equivalent resistance R_{eq} of the continuously variable resistive unit 431 with respect to the controlled voltage applied to the transistor 501 is schematically shown in FIG. 6. In this case, it is assumed R_{A}>>R_{B}.

The structure of the continuously variable resistance unit 431 is illustrated and described as an exemplary embodiment, other structures capable of providing continuously variable resistance are also embraced in scope of the present invention.

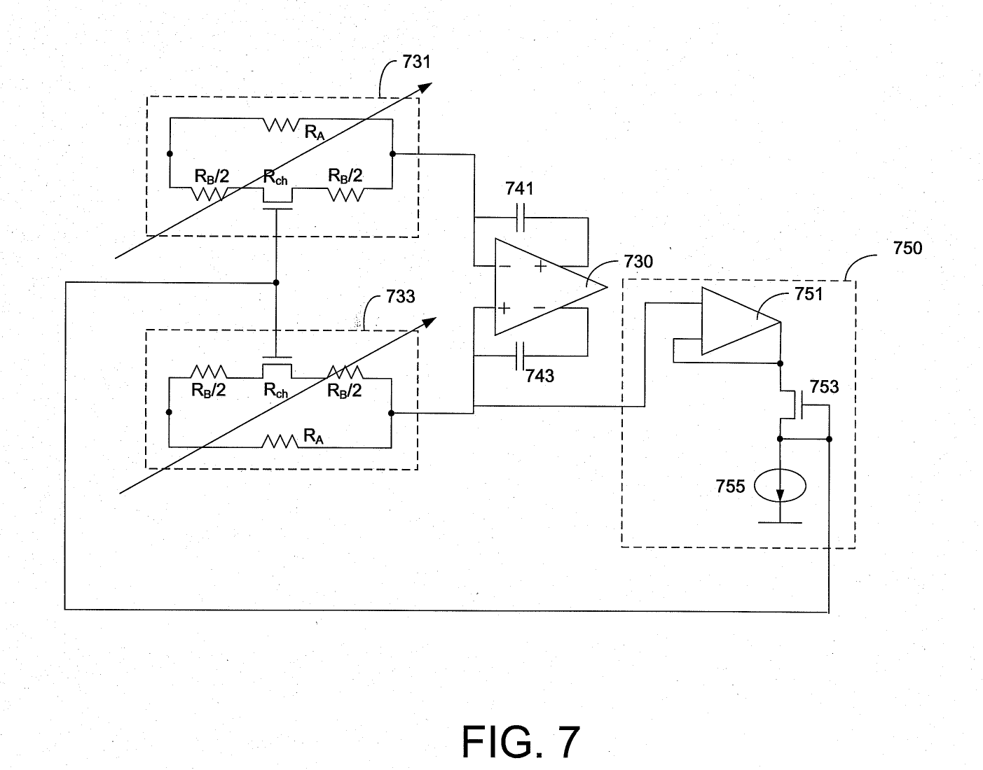

FIG. 7 illustrates an example of a low pass filtering device of the servo loop circuit in accordance with the present invention. In this drawing, the low pass filtering device has an integrator structure constituted by a differential amplifier 730, continuously variable resistive units 731, 733 and capacitors 741, 743, and a voltage controller 750.

As shown, the voltage controller 750 includes an amplifier 751, a transistor 753, and a current source 755. An input terminal of the amplifier 751 is connected with an input of the integrator, and another input terminal thereof is connected with an output terminal thereof. The transistor 753, which is implemented with a MOS transistor in this example, is connected between the amplifier 751 and the current source 755. The gate and source terminals of the MOS transistor 753 are coupled together and connected with the current source, and the drain terminal thereof is connected with the output terminal of the amplifier 751. It is noted that the voltage controller 750 is described therein as an implementation example. Any proper type of voltage controller can be used. The turn-on resistance Rch of the transistor in the continuously variable resistive units 731, 733 is varied by adjusting the current of the current source 755. Accordingly, continuous variation of the total resistance of the continuously variable resistive units 731, 733 can be obtained.

By controlling the resistance of the low pass filtering device to be continuously varied, the cutoff frequency thereof can be smoothly changed so as to eliminate the generation of DC offset. Therefore, the response time of the corner frequency converge of the servo loop can be limited without induction of additional DC offset.

While the preferred embodiment of the present invention has been illustrated and described in details, various modifications and alterations can be made by persons skilled in this art. The embodiment of the present invention is therefore described in an illustrative but not in a restrictive sense. It is intended that the present invention should not be limited to the particular forms as illustrated, and that all modifications and alterations which maintain the spirit and realm of the present invention are within the scope as defined in the appended claims.

What is claimed is:

1. A servo loop circuit comprising:
a signal path for a signal to be transmitted; and
a low pass filtering device for implementing low pass filtering function to the signal transmitted on the signal path, an output of the low pass filtering device being fed back to the signal path, the low pass filtering device having an equivalent capacitance and a variable equivalent resistance, a corner frequency depending on the equivalent capacitance and the equivalent resistance thereof varying continuously as the equivalent resistance changing continuously.

2. The circuit as claimed in claim 1, wherein the low pass filtering device comprises a low pass filter.

3. The circuit as claimed in claim 2, wherein the low pass filter comprises at least one continuously variable resistive unit having a variable resistance being able to change continuously.

4. The circuit as claimed in claim 3, wherein the continuously variable resistive unit comprises a transistor, a first resistive member connected with the transistor in series, and a second resistive member connected in parallel with the connection of the transistor and the first resistive member.

5. The circuit as claimed in claim 4, wherein the first resistive member comprises two resistors, the two resistors are respectively connected with the transistor in series.

6. The circuit as claimed in claim 4, wherein the second resistive member comprises a resistor.

7. The circuit as claimed in claim 4, wherein resistance of the transistor varies continuously by applying a controlled changing voltage to a control terminal of the transistor.

8. The circuit as claimed in claim 7, wherein the low pass filtering device further has a voltage controller for providing the controlled changing voltage, the voltage controller comprises a current source, a transistor connected with the current source and a differential amplifier connected with the transistor.

9. The circuit as claimed in claim 3, wherein the variable resistance of the continuously variable resistive unit is changed by applying a controlled changing voltage thereto.

10. The circuit as claimed in claim 9, wherein the low pass filtering device further has a voltage controller for providing the controlled changing voltage, the voltage controller comprises a current source, a transistor connected with the current source and a differential amplifier connected with the transistor.

11. The circuit as claimed in claim 1, wherein the low pass filtering device comprises an integrator.

12. The circuit as claimed in claim 11, wherein the integrator comprises at least one continuously variable resistive unit having a variable resistance being able to change continuously.

13. The circuit as claimed in claim 12, wherein the variable resistance of the continuously variable resistive unit is changed by applying a controlled changing voltage thereto.

14. The circuit as claimed in claim 1, further comprising a gain device on the signal path for providing the transmitted signal with a gain.

15. The circuit as claimed in claim 14, wherein the low pass filtering device comprises a low pass filter.

16. The circuit as claimed in claim 15, wherein the low pass filter comprises at least one continuously variable resistive unit having a variable resistance being able to change continuously.

17. The circuit as claimed in claim 16, wherein the variable resistance of the continuously variable resistive unit is changed by applying a controlled changing voltage thereto.

18. The circuit as claimed in claim 17, wherein the low pass filtering device further has a voltage controller for providing the controlled changing voltage.

19. The circuit as claimed in claim 18, wherein the voltage controller comprises a current source, a transistor connected with the current source and a differential amplifier connected with the transistor.

20. The circuit as claimed in claim 14, wherein the low pass filtering device comprises an integrator.

21. The circuit as claimed in claim 20, wherein the integrator comprises at least one continuously variable resistive unit having a variable resistance being able to change continuously.

22. The circuit as claimed in claim 21, wherein the variable resistance of the continuously variable resistive unit is changed by applying a controlled changing voltage thereto.

23. The circuit as claimed in claim 22, wherein the low pass filtering device further has a voltage controller for providing the controlled changing voltage.

24. The circuit as claimed in claim 23, wherein the voltage controller comprises a current source, a transistor connected with the current source and a differential amplifier connected with the transistor.
